(19) United States
(12) Patent Application Publication
(10) Pub. No.: US 2021/0146502 A1
(43) Pub. Date: May 20, 2021

(54) IN-SITU SPARK EROSION DRESSING SYSTEM AND METHOD THEREOF

(71) Applicant: NATIONAL TAIWAN NORMAL UNIVERSITY, Taipei (TW)

(72) Inventors: Shun-Tong Chen, Taipei (TW); Chun-Hung Hu, Taipei (TW)

(21) Appl. No.: 16/746,535

(22) Filed: Jan. 17, 2020

(30) Foreign Application Priority Data
Nov. 20, 2019 (TW) 108142196

(51) Int. Cl. B24B 53/00; H01L 21/67

(52) U.S. Cl. CPC B24B 53/001; H01L 21/67092

(57) ABSTRACT

An in-situ spark erosion dressing system includes a working platform, a moving platform, a cutting device, a spark erosion dressing device and a controller. The moving platform is coupled to the working platform and configured to load a work piece. The cutting device is coupled to the working platform and has a first cutting position and a first dressing position. The cutting device includes a wheel blade and the wheel blade cuts the work piece on the first cutting position. The spark erosion dressing device is coupled to the moving platform and includes a dressing electrode. The dressing electrode contacts the wheel blade on the first dressing position, and the spark erosion dressing device applies the discharge energy on the dressing electrode to dress the wheel blade. The controller controls the cutting device to move to the first cutting position according to a cutting resistance value.

### BACKGROUND OF THE INVENTION

### Field of the Invention

The present invention relates to an in-situ spark erosion dressing system, especially to an in-situ spark erosion dressing system which can increase cutting efficiency and reduce production cost.

### Description of the Prior Art

In recent years, the semiconductor technology has been well-developed and played a crucial role in many applications, such as 5G industries, electric vehicle industries, and artificial intelligence. And, the die division of wafer has been one of the important processes in the semiconductor processes. However, in the society that tends to miniaturize electronic products, the process requirements for tiny electronic components (such as ICs and semiconductor components) tend to be miniaturized, efficient, and low-cost. Therefore, in the process of die division, the quality and accuracy standards of each die are also improved, and how to effectively cut the die is one of the key technologies in the semiconductor process.

In general, the die division is mainly based on the laser processing technology and the traditional diamond wheel blade cutting method. Although the laser processing technology can achieve subtle, efficient and high-precision processing quality, the laser processing equipment is expensive. Besides, it is easy to generate heat-affected zones after laser processing, thereby causing damage to the die surface and reducing cutting quality. Therefore, in the current die-diving technology, the die is still cut by a conventional diamond wheel blade.

In the diamond wheel blade cutting equipment, most of its wheel blades use electroformed diamond wheel blades. However, since the electroformed diamond wheel blade has low diamond particle content and a low rigidity of the substrate, the eccentricity of the wheel blade is easily generated when the electroformed diamond wheel blade is disposed on the high speed spindle, and the wheel blade easily generates vibration during the cutting process, thereby affecting the quality of the die. Furthermore, when the wheel blade needs to be trimmed or dressed, the wheel blade needs to be removed from the wheel bearing, and the dressed wheel blade needs to be recalibrated and repeatedly tested whether it is concentric with the spindle, thereby affecting the production efficiency. Moreover, when the cutting portion of the wheel blade is stuffed by the chips, the wheel blade has to be directly discarded due to the loss of the cutting ability. Therefore, the production cost is also remarkably increased.

Therefore, it is necessary to develop a dressing equipment which can effectively improve cutting efficiency and reduce production cost to solve the problems of the prior art.

### SUMMARY OF THE INVENTION

Therefore, one category of the present invention is to provide an in-situ spark erosion dressing system which can in-situ correct and dress the wheel blade and remove the chips generated while cutting, to solve the problems of the prior art.

In one embodiment of the present invention, the in-situ spark erosion dressing system includes a working platform, a moving platform, a cutting device, a spark erosion dressing device and a controller. The moving platform is coupled to the working platform in a movable manner relative to the work platform, and the moving platform is configured to load a work piece. The cutting device is coupled to the working platform and has a first cutting position and a first dressing position. The cutting device includes a wheel blade, and the wheel blade cuts the work piece at the first cutting position. The spark erosion dressing device is coupled to the moving platform. The spark erosion dressing device includes a dressing electrode, and the dressing electrode contacts the wheel blade located at the first dressing position. The spark erosion dressing device applies a discharge energy on the dressing electrode to dress the wheel blade. The controller is connected to the moving platform and the cutting device. The controller controls the cutting device to move to the first dressing position with a moving path according to a cutting resistance value generated by the movement of the moving platform relative to the working platform while the cutting device cuts the wheel blade, to make the spark erosion dressing device dress the wheel blade with the discharge energy.

Wherein, the controller pre-stores an impedance threshold value. The controller controls the cutting device to move to the first dressing position when the cutting resistance value detected by the controller is greater than the impedance threshold value.

Wherein, the controller pre-stores the moving path, and the moving platform has a second cutting position and a second dressing position. The moving path includes a first moving platform path and a first cutting device path. The controller respectively controls the moving platform and the cutting device to move from the first cutting position and the second cutting position to the first dressing position and the second dressing position with the first moving platform path and the first cutting device path according to the moving path, to make the dressing electrode of the spark erosion dressing device couple to the wheel blade.

Furthermore, the controller pre-stores a dressing path. The dressing path includes a second moving platform path and a second cutting device path. The controller respectively controls the moving platform and the cutting device to move from the first dressing position and the second dressing position with the second moving platform path and the second cutting device path, to make the spark erosion dressing device dress the wheel blade by the dressing electrode.

Furthermore, the controller respectively controls the moving platform and the cutting device to move to the first cutting position and the second cutting position with the moving path after controlling the moving platform and the cutting device to move with the second moving platform path and the second cutting device path.

Wherein, the discharge energy includes a first discharge energy and a second discharge energy. The spark erosion dressing device corrects the wheel blade with the first discharge energy first, and then dresses the wheel blade with the second discharge energy. The first discharge energy is greater than the second discharge energy.

Furthermore, the in-situ spark erosion dressing system includes a sensor configured on the cutting device. The sensor is configured to sense a sensing value of the movement state of the wheel blade. The controller controls the spark erosion dressing device to dress the wheel blade with the second discharge energy according to the sensing value.

Wherein, the material of the wheel includes a conductive material, and the second discharge energy is greater than the melting point of the conductive material.

Wherein, the moving platform includes a plurality of positioning holes, and the spark erosion dressing device includes a plurality of positioning pins corresponding to the plurality of positioning holes. The spark erosion dressing device is detachably configured on the moving platform by the plurality of positioning pins.

Another one category of the present invention is to provide an in-situ spark erosion dressing method which can in-situ correct and dress the wheel blade and remove the chips generated while cutting, to solve the problems of the prior art.

In another one embodiment, the in-situ spark erosion dressing method includes the following steps of: detecting a cutting resistance value generated by a moving platform while a cutting device cuts a work piece on the moving platform at the cutting position; controlling the cutting device to move to a dressing position with a moving path according to the cutting resistance value, to make a dressing electrode of a spark erosion dressing device couple to a wheel blade of the cutting device; correcting the wheel blade with a first discharge energy according to a dressing path; sensing a sensing value of the movement state of the corrected wheel blade; dressing the wheel blade with the dressing path and a second discharge energy according to the sensing value; and controlling the corrected wheel blade of the cutting device to move to the cutting position with the moving path.

In summary, the in-situ spark erosion dressing system can determine the dressing timing according to the cutting resistance of the moving platform and dress without removing the wheel blade for maintaining the precision of the wheel blade, thereby increasing the production efficiency. Moreover, the in-situ spark erosion dressing system sequentially corrects and dresses the wheel blade by two different discharge energy to effectively increase the cutting quality of the wheel blade and reduce the production cost, thereby solving the problems of the prior art.

### BRIEF DESCRIPTION OF THE APPENDED DRAWINGS

FIG. 1 shows a schematic diagram of an in-situ spark erosion dressing system in an embodiment of the present invention.

FIG. 2 shows a schematic diagram of another one perspective of the in-situ spark erosion dressing system in FIG. 1.

FIG. 3 shows an exploded diagram of the in-situ spark erosion dressing system in FIG. 1.

FIG. 4 shows a schematic diagram of the in-situ spark erosion dressing system at the dressing position of FIG. 1.

FIG. 5 shows a schematic diagram of the wheel blade and the dressing electrode in the embodiment of FIG. 4.

FIG. 6 shows a schematic diagram of another one perspective of the wheel blade and the dressing electrode of FIG. 5.

FIG. 7 shows a flow diagram of an in-situ spark erosion dressing method in an embodiment of the present invention.

### DETAILED DESCRIPTION OF THE INVENTION

For the sake of the advantages, spirits and features of the present invention can be understood more easily and clearly, the detailed descriptions and discussions will be made later by way of the embodiments and with reference of the diagrams. It is worth noting that these embodiments are merely representative embodiments of the present invention, wherein the specific methods, devices, conditions, materials and the like are not limited to the embodiments of the present invention or corresponding embodiments. Moreover, the devices in the figures are only used to express their corresponding positions and are not drawing according to their actual proportion.

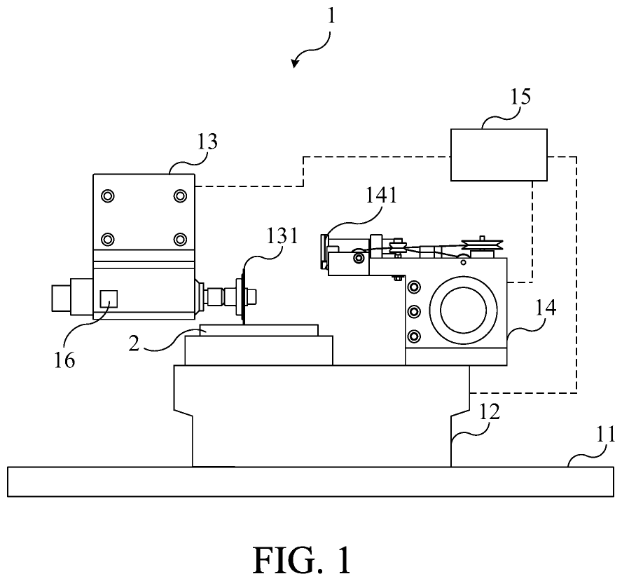

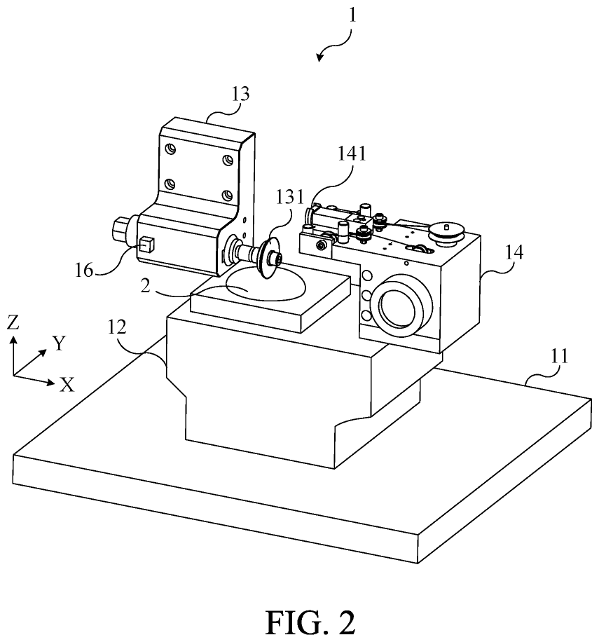

Please refer to FIG. 1 and FIG. 2. FIG. 1 shows a schematic diagram of an in-situ spark erosion dressing system 1 in an embodiment of the present invention. FIG. 2 shows a schematic diagram of another one perspective of the in-situ spark erosion dressing system 1 in FIG. 1. As shown in FIG. 1 and FIG. 2, the in-situ spark erosion dressing system 1 includes a working platform 11, a moving platform 12 and a cutting device 13. The moving platform 12 is coupled to the working platform 11 in a movable manner relative to the work platform 11, and the moving platform 12 is configured to load a work piece 2. In practice, the moving platform 12 can be a component with sliding rail, guiding rail, sliding block or roller, and the working platform 11 can include the structural component matched to the component of the moving platform 12. Therefore, the moving platform 12 can be configured on the working platform 11 and move relatively to the working platform 11. Moreover, the moving platform 12 can move on the plane formed by X axial and Y axial relative to the working platform 11 (as shown in FIG. 2). The work piece 2 can be a wafer or an uncut object. The work piece 2 can be configured on the moving platform 12 and disposed corresponding to the other side of the working platform 11. When the moving platform 12 moves on the working platform 11, the work piece 2 configured on the moving platform 12 also moves in the moving direction of the moving platform 12.

The cutting device 13 is coupled to the working platform 11 and has a first cutting position. The cutting device includes a wheel blade 131, and the wheel blade 131 can cut the work piece 2 at the first cutting position. In practice, the cutting device 13 is configured on the upper side of the moving platform 12 and on the same side with the work piece 2. In other words, the work piece 2 is located between the moving platform 12 and the cutting device 13. The cutting device 13 can includes a rotatable wheel bearing, and the wheel blade 131 is configured on the wheel bearing. The cutting device 13 can move perpendicularly to the plane of the working platform 11. Furthermore, the cutting device 13 can move in the Z axial direction (as shown in FIG. 2). The first cutting position can be the wheel blade position which the wheel blade 131 contacting and cutting the work piece 2. Therefore, the cutting device 13 can perpendicularly move to the first cutting position relative to the working platform 11 to make the wheel blade 131 cut the work piece 2.

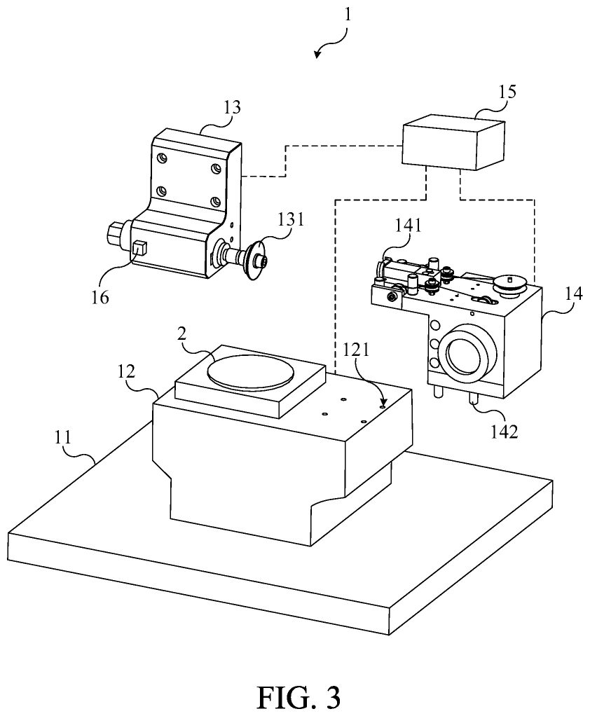

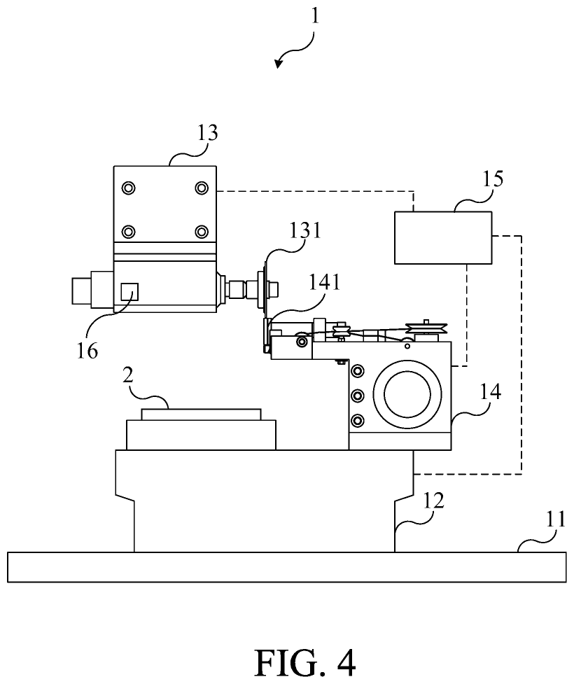

Please refer to FIG. 3 and FIG. 4. FIG. 3 shows an exploded diagram of the in-situ spark erosion dressing system 1 in FIG. 1. FIG. 4 shows a schematic diagram of the in-situ spark erosion dressing system 1 at the dressing position of FIG. 1. In this embodiment, the cutting device 13 further has a first dressing position, and the in-situ spark erosion dressing system 1 further includes a spark erosion dressing device 14 coupled to the moving platform 12. The spark erosion dressing device 14 includes a dressing electrode 141, and the dressing electrode 141 contacts the wheel blade 131 located at the first dressing position. The spark erosion dressing device 14 applies a discharge energy on the dressing electrode 141 to dress the wheel blade 131. In practice, the spark erosion dressing device 14 can be fixed on the moving platform 12, also can be movably configured on the moving platform 12. The dressing electrode 141 can be a wire electrode. When the spark erosion dressing device 14 dresses the wheel blade 131, the spark erosion dressing device 14 applies the discharge energy on the wire electrode, and the wire electrode contacts and dresses the wheel blade 131 in a continuous moving method (a loop by delivering wire and collecting wire). It is worth to notice that the shape of the dressing electrode 141 is not limited to thereof. The shape of the dressing electrode 141 can be a block, and can be designed as requirements. In one embodiment, the moving platform 12 includes a plurality of positioning holes 121, and the spark erosion dressing device 14 includes a plurality of positioning pins 142 corresponding to the plurality of positioning holes 121. The spark erosion dressing device 14 is movably configured on the moving platform 12 by the plurality of positioning pins 142. The spark erosion dressing device 14 can be a wire electrical spark erosion machine. The spark erosion dressing device 14 is configured on the moving platform 12 and located on the same side with the work piece 2. That is to say, the spark erosion dressing device 14 and the cutting device 13 are located on the same side of the moving platform 12. The first dressing position can be the wheel blade position which the wheel blade 131 contacts the dressing electrode 141. Therefore, the cutting device 13 can perpendicularly move to the first dressing position to make the wheel blade 131 contact the dressing electrode 141 of the spark erosion dressing device 14.

In this embodiment, in addition to the cutting device 13 has the first cutting position and the first dressing position, the moving platform 12 has a second cutting position and a second dressing position. In practice, the moving platform 12 can move in parallel to the plane of the working platform 11. Moreover, the moving platform 12 can move in the X axial and Y axial directions (as shown in FIG. 2). The second cutting position can be the moving platform position which the work piece 2 contacts the wheel blade 131. The second dressing position can be the moving platform position which the dressing electrode 141 of the spark erosion dressing device 14 configured on the moving platform 12 contacts the wheel blade 131. Therefore, when the moving platform 12 moves to the second cutting position which matches to the first cutting position, the wheel blade 131 of the cutting device 13 can contact and cut the work piece 2 on the moving platform 12. When the moving platform 12 moves to the second dressing position which matches the first dressing position, the dressing electrode 141 of the spark erosion dressing device 14 can contact the wheel blade 131 of the cutting device 13 to dress the wheel blade 131.

In this embodiment, the moving platform 12 generates a cutting resistance value while the moving platform 12 moves relatively to the working platform 11. In practice, the in-situ spark erosion dressing system 1 can drive the moving platform 12 to move at a current value by a power module. The minimum value of the force applied on the moving platform 12 should be equal to the static friction force of the moving platform 12, so as to make the moving platform 12 move. In other words, the minimum value of the current value of the power module applied on the moving platform 12 should be equal to the cutting resistance value of the moving platform 12, so as to make the moving platform 12 move. Furthermore, a kinetic friction force is generated between the wheel blade 131 and the work piece 2 when the wheel blade 131 contacts and cuts the work piece 2. The minimum value of the force applied on the moving platform 12 should be equal to the summary of the static friction force and the kinetic friction force, so as to make the moving platform 12 move. Therefore, the moving platform 12 can generate different cutting resistance values in different conditions. It is worth to notice that the types of the cutting resistance values are not limited thereto. The cutting resistance value can be speed value.

Please refer to FIG. 1. In this embodiment, the in-situ spark erosion dressing system 1 further includes a controller 15 connected to the moving platform 12 and the cutting device 13. The controller 15 controls the cutting device 13 to move to the first dressing position with a moving path according to the cutting resistance value generated by the movement of the moving platform 12 relative to the working platform 11, to make the spark erosion dressing device 14 dress the wheel blade 131 with the discharge energy. In practice, the controller 15 can be a computer or CNC controller. The controller 15 can respectively control the moving platform 12 and the cutting device 13 to move to the second cutting position and the first cutting position to make the wheel blade 131 cut the work piece 2. The controller 15 can detect the cutting resistance value generated by the moving platform 12, and can respectively control the moving platform 12 and the cutting device 13 to move to the second dressing position and the first dressing position according to the cutting resistance value.

Furthermore, in this embodiment, the controller 15 pre-stores an impedance threshold value. The controller 15 controls the cutting device 13 to move to the first dressing position when the cutting resistance value detected by the controller 15 is greater than the impedance threshold value. In practice, the impedance threshold value can be pre-stored in the controller 15, and the controller 15 can control the cutting device 13 to move to the first dressing position according to the cutting resistance value to dress the wheel blade 131. Since the cutting device 13 only can move in Z axial direction, the moving platform 12 should move on the working platform 11 to make the wheel blade 131 cut the work piece 2. When the wheel blade 131 contacts and cuts the work piece 2, the controller 15 detects the cutting resistance value generated by the movement of the moving platform 12. However, the chips generated by the wheel blade 131 while cutting the work piece 2 will be filled in the wheel blade 131 since the wheel blade 131 cuts the work piece for a long time. Besides, the sharpness of the wheel blade 131 is getting poor, so that the cutting resistance value of the moving platform 12 is increasing. That is to say, the current value required for controller 15 to drive the moving platform 12 to move is also increasing. Therefore, when the current value required for controller 15 to drive the moving platform 12 is greater than the impedance threshold value, the controller 15 controls the cutting device 13 to move to the first dressing position to dress the wheel blade 131.

In this embodiment, the controller 15 pre-stores a moving path, and the moving path includes a first moving platform path and a first cutting device path. The controller 15 respectively controls the cutting device 13 and the moving platform 12 to move to the first dressing position and the second dressing position according to the moving path to make the dressing electrode 141 of the spark erosion dressing device 14 couple to the wheel blade 131. In practice, the moving path can be a CNC path and include the moving path of the cutting device 13 and the moving platform 12. The first moving platform path includes the second cutting position and the second dressing position, and the first cutting device path includes the first cutting position and the first dressing position. When the controller 15 determines the wheel blade 131 of the cutting device 13 required to be dressed according to the cutting resistance value, the controller 15 respectively controls the cutting device 13 and the moving platform 12 to move from the first cutting position and the second cutting position to the first dressing position and the second dressing position with the first cutting device path and the first moving platform path. Therefore, the wheel blade 131 can be dressed directly by the movements of the cutting device 13 and the moving platform 12 without removing from the cutting device 13, so that the wheel blade 131 configured on the wheel bearing can maintain the concentricity and the cutting device 13 can maintain the cutting precision.

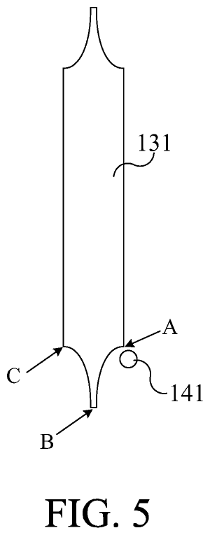

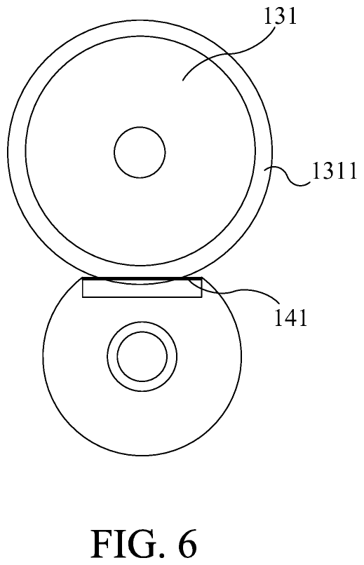

Please refer to FIG. 4, FIG. 5 and FIG. 6. FIG. 5 shows a schematic diagram of the wheel blade 131 and the dressing electrode 141 in the embodiment of FIG. 4. FIG. 6 shows a schematic diagram of another one perspective of the wheel blade 131 and the dressing electrode 141 of FIG. 5. In this embodiment, the controller 15 pre-stores a dressing path, and the dressing path includes a second moving platform path and a second cutting device path. In practice, the dressing path can include a dressing position A, dressing position B and dressing position C of the FIG. 4. Moreover, the second moving platform path and the second cutting device path both include the dressing position A, dressing position B and dressing position C. In addition to the second moving platform path and the second cutting device path include the dressing position A, dressing position B and dressing position C, the second cutting device path includes the first dressing position, and the second moving platform path includes the second dressing position. Therefore, the controller 15 respectively controls the moving platform 12 and the cutting device 13 to move with the second moving platform path and the second cutting device path after controlling the moving platform 12 and the cutting device 13 to move to the second dressing position and the first dressing position, to make the dressing electrode 141 of the spark erosion dressing device 14 dress the wheel blade 131. The order of the dressing path can be dressing position A, dressing position B and dressing position C, and can be dressing position A, dressing position B, dressing position C, dressing position B and dressing position A. Furthermore, the controller 15 can execute the dressing path multiple times to cause the spark erosion dressing device 14 to dress the wheel blade 131 multiple times. In one embodiment, the dressing position A can be the position that the wheel blade 131 contacts the dressing electrode 141 when the cutting device is located at the first dressing position and the moving platform is located at the second dressing position.

In this embodiment, after the controller 15 respectively controls the moving platform 12 and the cutting device 13 to move according to the dressing path to make the spark erosion dressing device 14 dress the wheel blade 131, the controller 15 respectively controls the moving platform 12 and the cutting device 13 to move to the first cutting position and the second cutting position according to the moving path. In practice, the controller 15 can pre-store a wheel blade dressing path. The wheel blade dressing path includes the moving path and the dressing path, and the order of the dressing path is moving path, dressing path and moving path. Moreover, the controller 15 can control the moving platform 12 and the cutting device 13 to move with the wheel blade dressing path according to the cutting resistance value. Therefore, when the controller 15 detects that the cutting resistance value is greater than the impedance threshold value, the controller 15 respectively controls the moving platform 12 and the cutting device 13 to move to the first dressing position and the second dressing position first. Then the controller 15 respectively controls the moving platform 12 and the cutting device 13 with the dressing path to make the spark erosion dressing device 14 dress the wheel blade 131. Then, the controller 15 respectively controls the moving platform 12 and the cutting device 13 to move to the first cutting position and the second position with the moving path. It is worth to notice that the executing time of the dressing path of the wheel blade dressing path is not limited to once, the executing time of the dressing path can be more than once. Therefore, when the wheel blade 131 needs to be dressed caused by cutting the work piece 2 for a long time, the in-situ spark erosion dressing system 1 can dress the wheel blade 131 by the spark erosion dressing device 14 without removing wheel blade 131, so that the wheel blade 131 configured on the wheel bearing can maintain the concentricity and the cutting device 13 can maintain the cutting precision.

In this embodiment, the aforementioned discharge energy includes a first discharge energy and a second discharge energy. The spark erosion dressing device 14 corrects the wheel blade 131 with the first discharge energy first, and then dresses the wheel blade 131 with the second discharge energy. Wherein, the first discharge energy is greater than the second discharge energy. In practice, the discharge energy can include a discharge waveform having a frequency, a peak value and a pulse width. After the controller 15 respectively controls the moving platform 12 and the cutting device 13 to move to the first dressing position and the second dressing position, the spark erosion dressing device 14 applies the discharge energy on the dressing electrode 141 and the controller 15 respectively to control the moving platform 12 and the cutting device 13 with the dressing path to make the dressing electrode 141 dress the wheel blade 131. Since the discharge energy is applied on the dressing electrode 141 to cause the dressing electrode 141 generating a high temperature, the high temperature of the dressing electrode 141 generated by the discharge energy melts the melting point of the material of the wheel blade 131 to make the dressing electrode 141 correct and dress the wheel blade 131. In practice, the first discharge energy can be greater than the melting point of the material of the wheel blade 131. When the wheel blade 131 cuts the work piece 2 for a long time, the shape of the wheel blade 131 may be broken or damaged. Therefore, the spark erosion dressing device 14 can apply the first discharge energy on the dressing electrode 141 to correct the wheel blade 131 to maintain the concentricity and avoid skew. The second discharge energy can be smaller than the melting point of the material of the wheel blade 131. When the spark erosion dressing device 14 corrects the wheel blade 131 with the first energy, the wheel blade 131 may generate burrs and residues. Therefore, the spark erosion dressing device 14 can apply the second discharge energy on the dressing electrode 141 to dress the wheel blade 131 for maintaining the precision.

Furthermore, the spark erosion dressing device 14 can dress the wheel blade 131 with the first discharge energy and the second discharge energy as the controller 15 executes once of the dressing path. For example, when the orders of the dressing path are dressing position A, dressing position B, dressing position C, dressing position B and dressing position A, the spark erosion dressing device 14 can correct the wheel blade 131 at the paths of dressing position A, dressing position B and dressing position C, and the spark erosion dressing device 14 can dress the wheel blade 131 at the paths of dressing position C, dressing position B and dressing position A. In another one embodiment, the controller 15 executes the dressing path twice, and the spark erosion dressing device 14 respectively dresses the wheel blade 131 with the first discharge energy and the second discharge energy on each dressing path.

The aforementioned material of the wheel blade 131 includes a conductive material, and the second discharge energy is greater than the melting point of the conductive material. In practice, the conductive material can be a strong conductive material (such as Copper, Cobalt and Nickel) and weak conductive material (such as cermets), but it is not limited thereto. The wheel blade 131 can include the diamond material and the conductive material, and the wheel blade 131 can be formed by connecting the diamond with the conductive material as a binder or a catalyst. When the spark erosion dressing device 14 corrects the wheel blade 131 with the first discharge energy, the first discharge energy is greater than the melting point of the diamond and the conductive material, so that the dressing electrode 141 can correct the shape of the wheel blade 131. When the spark erosion dressing device 14 corrects the wheel blade 131 with the second discharge energy, the second discharge energy is between the melting point of the diamond and the conductive material. Therefore, the dressing electrode 141 can melt the conductive material to expose the diamond, thereby improving the sharpness of the wheel blade 131.

In one embodiment, the material of the wheel blade is a polycrystalline diamond. In practice, the first discharge energy can be greater than the melting point of the diamond. When the spark erosion dressing device 14 corrects the wheel blade with the first discharge energy, the dressing electrode 141 carbonizes the polycrystalline diamond of the wheel blade and corrects the wheel blade along the dressing path. When the spark erosion dressing device 14 dresses the wheel blade with the second discharge energy, the dressing electrode 141 only melts and removes the graphite metamorphic layer on the surface of the wheel blade to expose the diamond blade, thereby improving the sharpness of the wheel blade. Moreover, when the spark erosion dressing device 14 dresses the wheel blade with the second discharge energy, the melting grooves are generated between the diamonds. Therefore, the chips generated by the wheel blade cutting the work piece will be filled into the melting grooves of the wheel blade, thereby reducing the cutting resistance value of the moving platform.

In this embodiment, the in-situ spark erosion dressing system 1 further includes a sensor 16 configured on the cutting device 13. The sensor 16 is configured to sense a sensing value of motion state of the wheel blade 131. The controller 15 controls the spark erosion dressing device 14 to dress the wheel blade 131 with the second discharge energy according to the sensing value. In practice, the sensor 16 can be a vibration sensor. When the spark erosion dressing device 14 corrects the wheel blade 131 with the first discharge energy, the cutting device 13 generates vibration since the dressing electrode 141 contacting and correcting the wheel blade 131. Therefore, when the vibration sensing value sensed by the sensor 16 has a significant change, the controller 15 still controls the spark erosion dressing device 14 to correct the wheel blade 131 with the first discharge energy. When the vibration sensing value sensed by the sensor 16 does not change significantly, it means that the wheel blade has been corrected. At this time, the controller 15 controls the spark erosion dressing device 14 to dress the wheel blade 131 with the second discharge energy.

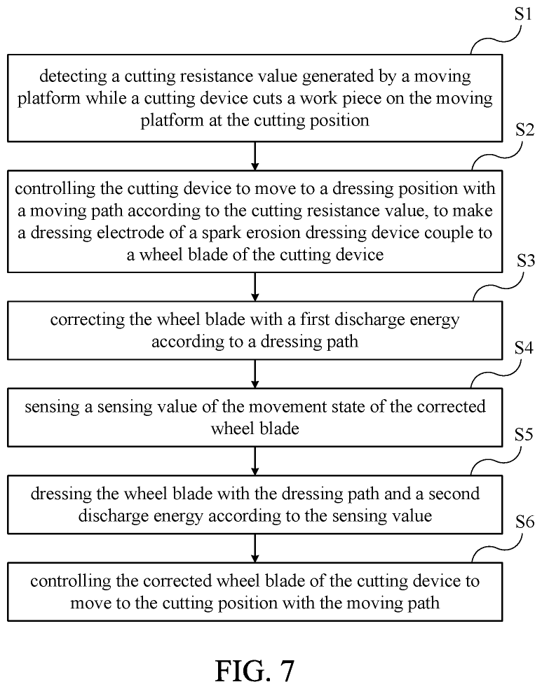

Please refer to FIG. 7 and FIG. 4. FIG. 7 shows a flow diagram of an in-situ spark erosion dressing method in an embodiment of the present invention. In this embodiment, the in-situ spark erosion dressing method can be executed by the in-situ spark erosion dressing system of FIG. 4. As shown in FIG. 7, the in-situ spark erosion dressing method of this embodiment includes the following steps: in the step S1, detecting a cutting resistance value generated by a moving platform 12 while a cutting device 13 cuts a work piece 2 on the moving platform 12 at the cutting position; in the step S2, controlling the cutting device 13 to move to a dressing position with a moving path according to the cutting resistance value, to make a dressing electrode 141 of a spark erosion dressing device 14 couple to a wheel blade 131 of the cutting device 13; in the step S3, correcting the wheel blade 131 with a first discharge energy according to a dressing path; in the step S4, sensing a sensing value of the movement state of the corrected wheel blade 131; in the step S5, dressing the wheel blade 131 with the dressing path and a second discharge energy according to the sensing value; and in the step S6, controlling the corrected wheel blade 131 of the cutting device 13 to move to the cutting position with the moving path. The functions of the components or devices mentioned in this embodiment are the same with those of the components or devices mentioned in aforementioned embodiments, and will not be further described herein.

In summary, the in-situ spark erosion dressing system can determine the dressing timing according to the cutting resistance of the moving platform, and controls the moving platform and the cutting device without removing the wheel blade to make the dressing electrode of the spark erosion dressing device dress the wheel blade for maintaining the precision of the wheel blade, thereby increasing the production efficiency. Moreover, the in-situ spark erosion dressing system sequentially corrects and dresses the wheel blade by two different discharge energy to effectively increase the cutting quality of the wheel blade and reduce the production cost, thereby solving the problems of the prior art.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An in-situ spark erosion dressing system, comprising:
a working platform;
a moving platform coupled to the working platform in a movable manner relative to the work platform, the moving platform being configured to load a work piece;
a cutting device coupled to the work platform and having a first cutting position and a first dressing position, the cutting device comprising a wheel blade, and the wheel blade cutting the work piece at the first cutting position;
a spark erosion dressing device coupled to the moving platform, the spark erosion dressing device comprising a dressing electrode, and the dressing electrode contacting the wheel blade located at the first dressing position, the spark erosion dressing device applying a discharge energy on the dressing electrode to dress the wheel blade; and
a controller connected to the moving platform and the cutting device, the controller controlling the cutting device to move to the first dressing position with a moving path according to a cutting resistance value generated by the movement of the moving platform relative to the working platform while the cutting device cuts the wheel blade, to make the spark erosion dressing device dress the wheel blade with the discharge energy.

2. The system of claim 1, wherein the controller pre-stores an impedance threshold value, the controller controls the cutting device to move to the first dressing position when the cutting resistance value detected by the controller is greater than the impedance threshold value.

3. The system of claim 1, wherein the controller pre-stores the moving path, the moving platform has a second cutting position and a second dressing position, the moving path comprises a first moving platform path and a first cutting device path, the controller respectively controls the moving platform and the cutting device to move from the first cutting position and the second cutting position to the first dressing position and the second dressing position with the first moving platform path and the first cutting device path according to the moving path, to make the dressing electrode of the spark erosion dressing device couple to the wheel blade.

4. The system of claim 3, wherein the controller pre-stores a dressing path, the dressing path comprises a second moving platform path and a second cutting device path, the controller respectively controls the moving platform and the cutting device to move from the first cutting position and the second cutting position with the second moving platform path and the second cutting device path according to the dressing path, to make the spark erosion dressing device cut the wheel blade by the dressing electrode.

5. The system of claim 4, wherein the controller respectively controls the moving platform and the cutting device to move to the first cutting position and the second cutting position with the moving path after controlling the moving platform and the cutting device to move by the second platform path and the second cutting device path.

6. The system of claim 1, wherein the discharge energy comprises a first discharge energy and a second discharge energy, the spark erosion dressing device corrects the wheel blade with the first discharge energy first, and then the spark erosion dressing device dresses the wheel blade with the second discharge energy, the first discharge energy is greater than the second discharge energy.

7. The system of claim 6, further comprising a sensor configured on the cutting device, the sensor being configured to sense a sensing value of the movement state of the wheel blade, the controller controlling the spark erosion dressing device to dress the wheel blade with the second discharge energy according to the sensing value.

8. The system of claim 6, wherein the material of the wheel blade comprises a conductive material, and the second discharge energy is greater than the melting point of the conductive material.

9. The system of claim 1, wherein the moving platform comprises a plurality of positioning holes, and the spark erosion dressing device comprises a plurality of positioning pins corresponding to the plurality of positioning holes, the spark erosion dressing device is detachably configured on the moving platform by the plurality of positioning pins.

10. An in-situ spark erosion dressing method, comprising the following steps of:
detecting a cutting resistance value generated by a moving platform while a cutting device cuts a work piece on the moving platform at the cutting position;
controlling the cutting device to move to a dressing position with a moving path according to the cutting resistance value, to make a dressing electrode of a spark erosion dressing device couple to a wheel blade of the cutting device;
correcting the wheel blade with a first discharge energy according to a dressing path;
sensing a sensing value of the movement state of the corrected wheel blade;
dressing the wheel blade with the dressing path and a second discharge energy according to the sensing value; and
controlling the corrected wheel blade of the cutting device to move to the cutting position with the moving path.
